(19) United States
(12) Patent Application Publication
(10) Pub. No.: US 2006/0177566 A1
(43) Pub. Date: Aug. 10, 2006

(54) Anodizing system with a coating thickness monitor and an anodized product

(76) Inventor: Joseph K. Price, Nebo, NC (US)

Correspondence Address: KILPATRICK STOCKTON LLP, 1001 WEST FOURTH STREET, WINSTON-SALEM, NC, 27101, US

(21) Appl. No.: 11/327,971

(22) Filed: Jan. 9, 2006

Related U.S. Application Data
(60) Provisional application No. 60/642,077, filed on Jan. 7, 2005.

(51) Int. Cl. C23C 16/52; B05C 11/00

(52) U.S. Cl. 427/8; 118/712; 118/692; 118/666

(57) ABSTRACT

An intelligent coating system for forming a product on at least a portion of a substrate is disclosed. The intelligent coating system includes a coating applicator, a thickness monitor, a multiple-axis device, and, optionally, at least one controller. The thickness monitor measures the thickness of at least a portion of the product on the substrate formed by operation of the coating applicator and is capable of converting a coating system into an intelligent coating system. The multiple-axis device facilitates a relative movement of at least a portion of the coating applicator and the substrate. The at least one controller communicates with at least the thickness monitor.

This application claims priority under 35 USC §119(e) to U.S. Provisional Application 60/642,077 filed on Jan. 7, 2005, the contents of which are incorporated by reference in its entirety.

### BACKGROUND OF THE INVENTION

The coating of metallic substrates such as aluminum and zinc is known. Coating is done for practical and aesthetic reasons. From a practical perspective, the creation of a coating on the surface of a metallic substrate contributes to the substrate's wear resistance, corrosion resistance, and oxidation resistance. From an aesthetic perspective, the creation of a coating including a dye and/or pigment for coloration on the surface of a metallic substrate contributes to substrate's consumer appeal. In both industrial and aesthetic applications, it is desirable to control the thickness of the coating as well as the consistency over a prescribed surface area. Commonly, coating thickness is determined by destructive methods. For example, in a batch spray painting system, control coupons made of the same material as a substrate to be coated are included in the spray painting system. At intermediate times during the spray painting process, a control coupon is removed from the spray painting system and destroyed in a manner that permits determining the coating thickness.

One destructive method includes mounting a control coupon in a Bakelite cross-section, polishing the mounted coupon to a mirror finish, and examining the polished cross-section using an optical microscope to determine the coating thickness. A second destructive method includes cutting or breaking a control coupon to expose a cross-section and examining the cross-section using scanning electron microscopy to determine the coating thickness. These destructive methods are cumbersome in production.

Both destructive methods delay production because of the time taken to remove and prepare control coupons for determining coating thickness. During the delay, the spray painting system is idle. An alternative is to remove the substrate from the spray painting system while determining coating thickness and replace it with a second product and corresponding control coupons. In this case, a storage area for the substrate removed from the spray painting system during a coating thickness determination would be required at the production site. Although using a spray painting system alternatively with multiple products provides a solution to production delay, coating flaws can be introduced by surface contamination during storage. During storage, the original coating on the product may also be damaged during removal from and replacement into the spray painting system. Particulate matter such as dust also may attach to the surface to introduce further interfacial flaws between the original coating and the further coating.

The above destructive methods have another serious flaw, namely, that the determined coating thickness is that of a control coupon and not of the product. Thus, the coating thickness of the product is only an estimate and the coating thickness consistency over the entire surface of the product is unknown.

Thus, there remains a need for a new and improved coating system that includes a thickness monitor that nondestructively determines the coating thickness on a product, while at the same time has the ability to control the coating system. Also, there remains a need for a coating thickness monitor that is capable of converting a coating system to an intelligent coating system.

### BRIEF SUMMARY OF THE INVENTION

The present invention relates generally to an intelligent coating system including a thickness monitor and, more particularly, to a system for regulating a product thickness on a substrate as it is being formed as well as measuring the product thickness subsequent to its formation.

### BRIEF DESCRIPTION OF SEVERAL VIEWS OF THE DRAWING

The patent or application file contains at least one drawing executed in color. Copies of this patent or patent application publication with color drawing(s) will be provided by the Office upon request and payment of the necessary fee.

FIG. 1 depicts an intelligent coating system including a thickness monitor according to an aspect of the present invention;

FIG. 2 depicts details of the intelligent coating system including a thickness monitor of FIG. 1 according to an aspect of the present invention;

FIG. 3A depicts an applicator and a probe configuration of an intelligent coating system adjacent to a substrate useable with an anodizing system as depicted in FIGS. 1 and 2 according to an aspect of the present invention;

FIG. 3B depicts an alternative applicator and a probe configuration of an intelligent coating system adjacent to a substrate useable with an anodizing system as depicted in FIGS. 1 and 2 according to an aspect of the present invention;

FIG. 3C depicts another alternative applicator and a probe configuration of an intelligent coating system adjacent to a substrate useable with an anodizing system as depicted in

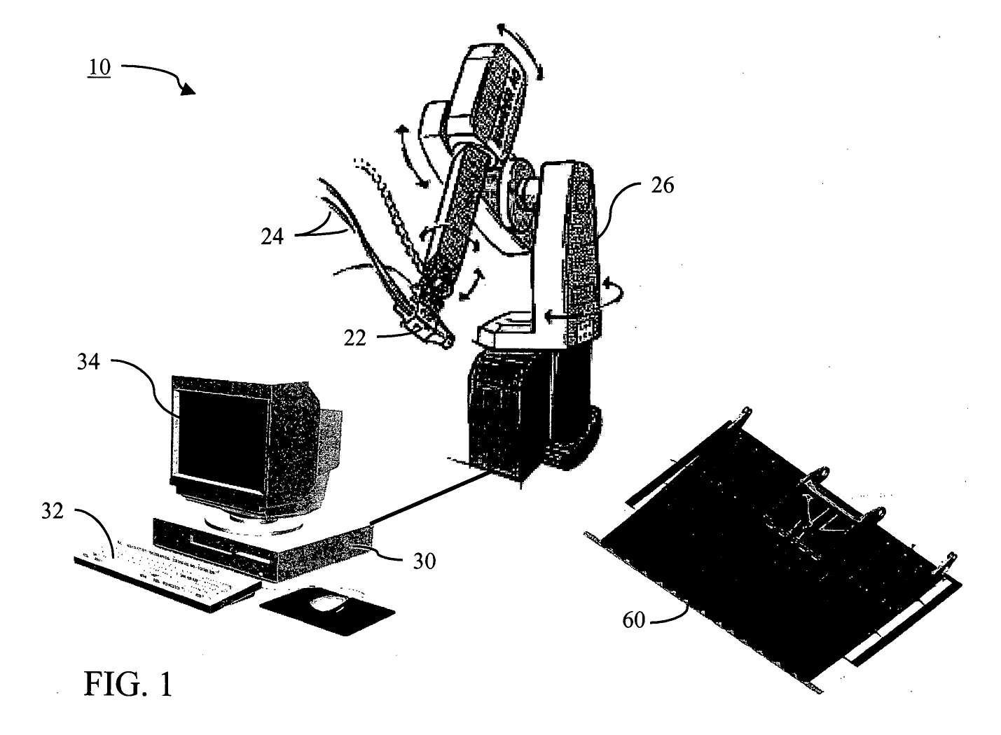

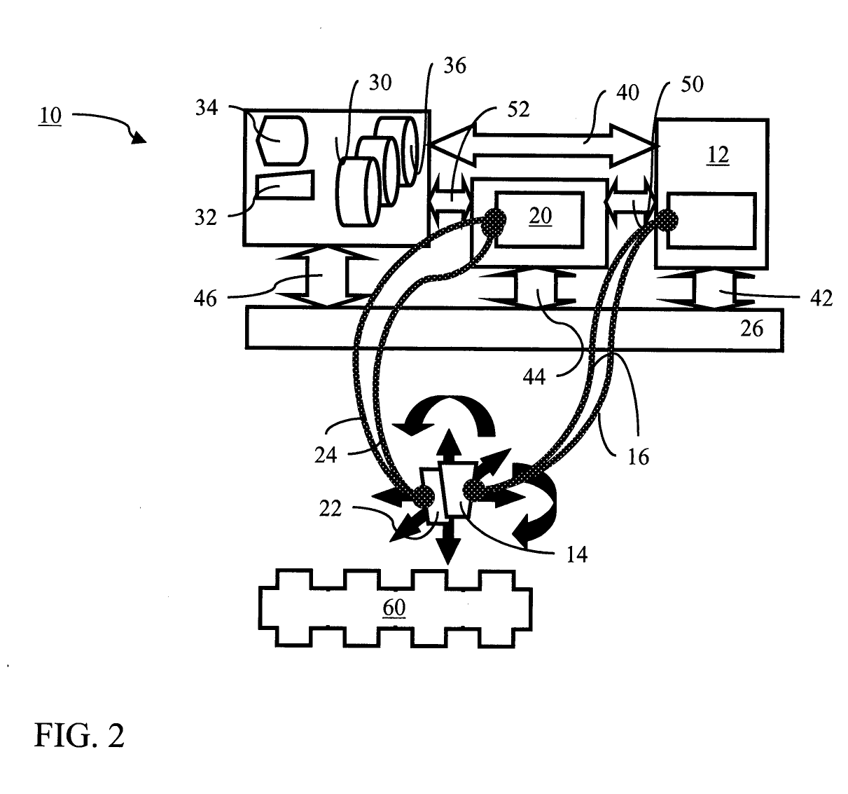

FIGS. 1 and 2 according to an aspect of the present invention;

FIG. 4 depicts a diagram of a product on a substrate formable using an intelligent coating system as depicted in FIGS. 1 and 2 according to an aspect of the present invention;

FIG. 5 depicts a controller block diagram useable with teaching an intelligent coating system as depicted in FIGS. 1 and 2 according to an aspect of the present invention;

FIG. 6 depicts a plurality of data matrices useable with teaching an intelligent coating system as depicted in FIGS. 1 and 2 according to an aspect of the present invention;

FIG. 7 depicts a linear and nonlinear cumulative product thickness graph useable with teaching an intelligent coating system as depicted in FIGS. 1 and 2 according to an aspect of the present invention;

FIG. 8 depicts a validation sample;

FIG. 9 depicts an average and standard deviation of each measurement for comparison to the micro-graph data;

FIG. 10 depicts a scanned area comparison to a fixed-point measurement;

FIG. 11 depicts three (validation) test panels with three different thickness levels;

FIG. 12 depicts a comparison of scanned thickness data with fixed point data to demonstrate fixed point accuracy of the system and to demonstrate precision of the instrument;

FIG. 13A and FIG. 13B depict thickness variation within each coupon/location for a given run;

FIG. 14A and FIG. 14B depict thickness variation within each coupon/location for a given run;

FIG. 15A and FIG. 15B depict thickness variation within each coupon/location for a given run;

FIG. 16A and FIG. 16B. depict thickness variation within each coupon/location for a given run; and

FIG. 17A and FIG. 17B depict an abstract shape and details thereof.

### DETAILED DESCRIPTION OF THE INVENTION

The present invention is directed to an intelligent coating system for forming a product on at least a portion of a substrate. The intelligent coating system includes a coating applicator, a thickness monitor, a multiple-axis device, and, optionally, at least one controller. The coating applicator may be any of the type generally known in the art, such as for example, a spray gun and the like. The thickness monitor measures the thickness of at least a portion of the product on the substrate formed by operation of the coating applicator. The thickness monitor may include at least one radiation source, at least one probe, and at least one detector. The at least one radiation source is capable of being directed at at least a portion of the product on the substrate. The at least one probe is capable of capturing at least a portion of the radiation reflected and refracted by the product on the substrate. The captured radiation is at least a portion of the radiation directed at the product on the substrate from the radiation source. The at least one detector communicates with the at least one probe. The at least one detector is capable of processing the captured radiation to determine at least the thickness of the product on the coated substrate. The thickness monitor is capable of converting the coating system into an intelligent coating system. The multiple-axis device is capable of facilitating a relative movement of at least a portion of the coating applicator and the substrate. The at least one controller communicates with at least the thickness monitor. The at least one controller may communicates with at least the thickness monitor and one probe.

The at least one controller may communicate with at least the multiple-axis device, the coating applicator, and the thickness monitor. Also, the at least one controller may regulate a relative movement of the probe and the substrate. Further, the at least one controller may regulate at least one process parameter of the coating applicator, such as, for example, a rate of the relative movement of at least a portion of the coating applicator and the substrate, a distance between at least a portion of the coating applicator and the substrate, an angle between at least a portion of the coating applicator and the substrate, a coating application temperature, a coating application pressure, a coating application flowrate, a coating application coating/propellant ratio, a coating application solids content, and any combination thereof. Moreover, the at least one controller may be capable of learning a process for providing a predetermined product thickness distribution over the substrate. In addition, alternatively, the at least one controller may be capable of learning a process for providing a predetermined endpoint product thickness distribution over the substrate.

The thickness monitor further may include a coupling system. When light radiation is used, the coupling system is an optical couple, such as, for example, an optical fiber. The optical fiber is not limited to a single optical fiber and thus may be a plurality of optical fibers.

Further, the thickness monitor may include an additional coupling system capable of transmitting at least a portion of the radiation from the at least one radiation source to direct at least a portion of the radiation at at least a portion of the product on the substrate. The additional coupling system may be an additional optical couple such as, for example, an optical fiber. Likewise, this additional optical fiber is not limited to a single optical fiber and thus may be a plurality of optical fibers.

The thickness monitor further may include a supplementary coupling system capable of at least one of: (a) transmitting additional captured radiation from the at least one probe to the at least one detector; (b) transmitting at least a portion of the radiation from at least one additional radiation source to direct at least a portion of the additional radiation at at least a portion of the product on the substrate; and (c) transmitting at least a portion of the additional radiation from at least one additional radiation source to direct the at least a portion of the additional radiation at at least a portion of the product on the substrate and transmitting the additional captured radiation from the at least one probe to the at least one detector, the additional captured radiation being at least a portion of the additional radiation directed at the product on the substrate from the at least one additional radiation source.

The supplementary coupling system may be an additional optical couple, such as, for example, an optical fiber. As noted above, this additional optical fiber is not limited to a single optical fiber and thus may be a plurality of optical fibers.

The coupling system and the supplementary coupling system of the thickness monitor may be selected to be capable of transmitting a broad spectral range of captured radiation from the at least one probe to the at least one detector.

The at least one radiation source of the thickness monitor may be polychromatic such as, for example, at least one of ultraviolet radiation, visible radiation, infrared radiation, and combinations thereof.

Alternatively, the at least one radiation source of the thickness monitor may be monochromatic. Such a system further may include an additional radiation source. The additional radiation source may be polychromatic such as, for example, at least one of ultraviolet radiation, visible radiation, infrared radiation, and combinations thereof. Alternatively, the additional radiation is monochromatic.

A spectral range of the at least one radiation source and a spectral range of the additional radiation source partially overlap. The partial overlap may increase at least one of a signal to noise ratio for the captured radiation, a total spectral range of captures radiation, and combinations thereof.

The at least one radiation source and the additional radiation source may be visible radiation and the other of the at least radiation source and the additional radiation source may be infrared radiation.

The at least one probe of the thickness monitor further may include a collimator. The collimator may facilitate a depth of field of a sufficient magnitude to measure the product thickness. The at least one probe may substantially juxtapose the coating applicator. Alternatively, the at least one probe may be substantially separate of the coating applicator.

The at least one detector of the thickness monitor may include an interferometer. Alternatively, the thickness monitor may process the captured radiation to determine the thickness by at least one of: (a) using a color; (b) using an interference pattern; (c) using an amount of absorbed radiation; (d) using an intensities ratio of a minimum reflected radiation wavelength and a maximum reflected radiation wavelength; (e) using a Fast Fourier Transformation (FFT) of the captured radiation; (f) displacement using eddy current; (g) displacement using capacitance, (h) displacement using an optics or laser, and (i) combinations thereof.

Accordingly, one aspect of the present invention is to provide an intelligent coating system for forming a product on at least a portion of a substrate. The intelligent coating system includes a coating applicator, a thickness monitor, and a multiple-axis device. The thickness monitor measures the thickness of at least a portion of the product on the substrate formed by operation of the coating applicator. The thickness monitor includes at least one probe and at least one detector. The at least one probe is capable of communicating with at least a portion of the product on the substrate without contacting either. The at least one detector communicates with the at least one probe and is capable of processing the communication of the at least one probe with the at least a portion of the product to allow a determination of at least the thickness of the product on the substrate. The multiple-axis device is capable of facilitating a relative movement of at least a portion of the coating applicator and the substrate.

Another aspect of the present invention is to provide a thickness monitor for measuring the thickness of at least a portion of a product formed on at least a portion of a substrate in a coating system that includes a coating applicator and a multiple-axis device. The multiple-axis device facilitates a relative movement of at least a portion of the coating applicator and the substrate. The thickness monitor includes at least one radiation source, at least one probe, and at least one detector. The at least one radiation source is capable of being directed at at least a portion of the product on the substrate. The at least one probe is capable of capturing at least a portion of the radiation reflected and refracted by the product on the substrate. Note that the captured radiation is at least a portion of the radiation directed at the product on the substrate from the radiation source. The at least one detector communicates with the at least one probe and is capable of processing the captured radiation to determine at least the thickness of the product on the coated substrate. The thickness monitor facilitates the conversion of the coating system into an intelligent coating system.

Still another aspect of the present invention is to provide an intelligent coating system for forming a product on at least a portion of a substrate. The intelligent coating system includes a coating applicator, a thickness monitor, a multiple-axis device, and, optionally, at least one controller. The coating applicator may be any of the type generally known in the art, such as for example, a spray gun and the like. The thickness monitor measures the thickness of at least a portion of the product on the substrate formed by operation of the coating applicator. The thickness monitor may include at least one radiation source, at least one probe, and at least one detector. The at least one radiation source is capable of being directed at at least a portion of the product on the substrate. The least one probe is capable of capturing at least a portion of the radiation reflected and refracted by the product on the substrate. The captured radiation is at least a portion of the radiation directed at the product on the substrate from the radiation source. The at least one detector communicates with the at least one probe. The at least one detector is capable of processing the captured radiation to determine at least the thickness of the product on the coated substrate. The thickness monitor is capable of converting the coating system into an intelligent coating system. The multiple-axis device is capable of facilitating a relative movement of at least a portion of the coating applicator and the substrate. The at least one controller communicates with at least the thickness monitor.

Yet another aspect of the present invention is to teach a coating system to form a product on at least a portion of a substrate by coating the substrate. Among other steps, the method includes setting the operating parameters, applying a coating, measuring a thickness, relating the operating parameters and the product thickness, and determining whether a product thickness distribution meets a prescribed product thickness distribution. Initially, the setting of the operating parameters for the coating process are set to initial prescribed operating parameters. The coating is applied to at least a portion of the substrate to create the product, while at the same time recording the operating parameters of the coating process. The measuring of the thickness includes communicating with at least a portion of the product on the substrate without contacting either and processing the communication with the at least a portion of the product to allow a determination of at least the thickness of the product on the substrate. The operating parameters and the product thickness are then related with the location the substrate. Then, a determination is made as to whether a product thickness distribution meets a prescribed product thickness distribution. If the product thickness distribution meets the prescribed product thickness distribution, either the application of the coating is repeated to build up the product thickness, or the substrate is replaced with another substrate and the coating is repeated. Otherwise, the substrate is replaced with another substrate, the operating parameters are set to secondary prescribed operating parameters, and the coating is repeated using the new parameters. After a plurality of coating runs, a reconciling of the operating parameters and the product thickness from the plurality of coating runs may be used to create a dynamic control of the coating system.

These and other aspects of the present invention will become apparent to those skilled in the art after a reading of the following description of the preferred embodiments, when considered with the drawings.

In the following description, like reference characters designate like or corresponding parts throughout the several views. Also in the following description, it is to be understood that such terms as “forward,” “rearward,” “left,” “right,” “upwardly,” “downwardly,” and the like are words of convenience and are not to be construed as limiting terms.

Referring now to the drawings in general and FIG. 1 in particular, it will be understood that the illustrations are for the purpose of describing a preferred embodiment of the invention and are not intended to limit the invention thereto. As best seen in FIG. 1 and FIG. 2, an intelligent coating system 10 includes a thickness monitor 12, a coating applicator 20, and a multiple-axis device 26. A substrate 60 is juxtaposed proximate to the coating applicator 20. The intelligent coating system 10 may further include a controller 30.

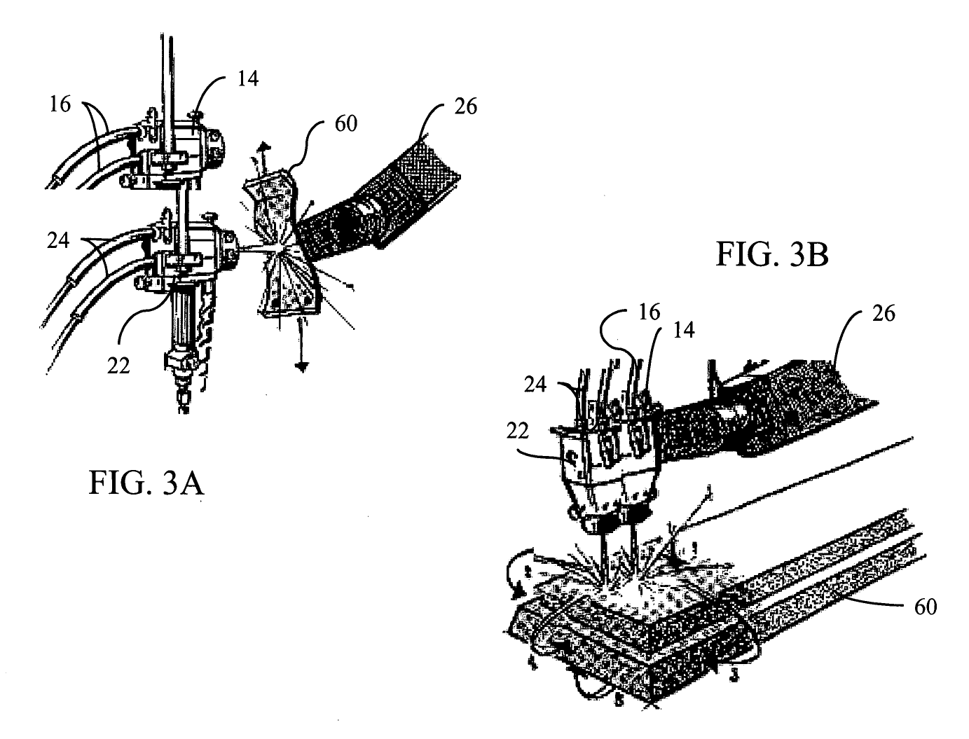

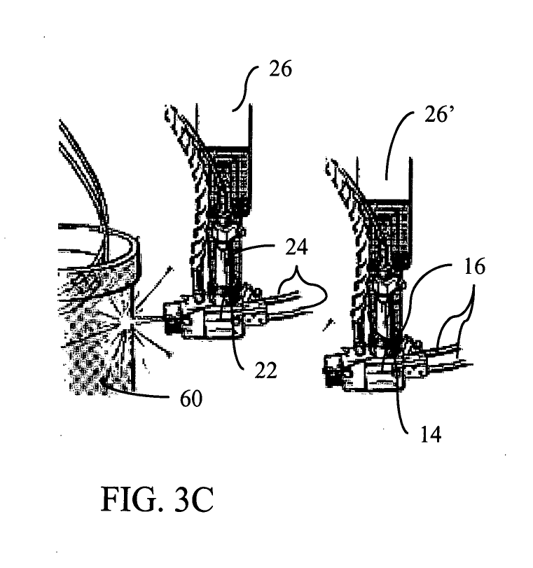

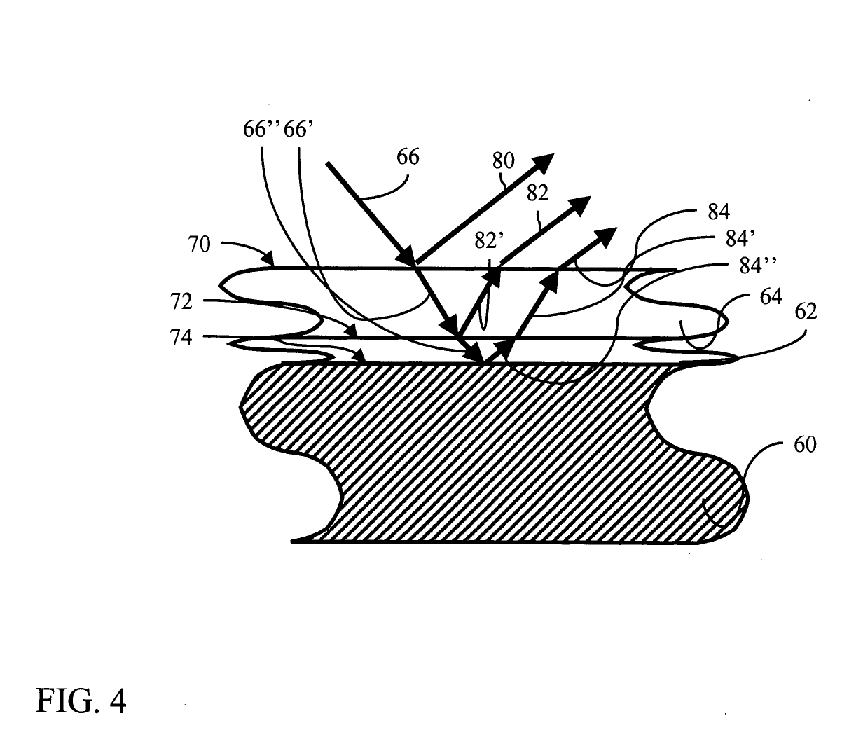

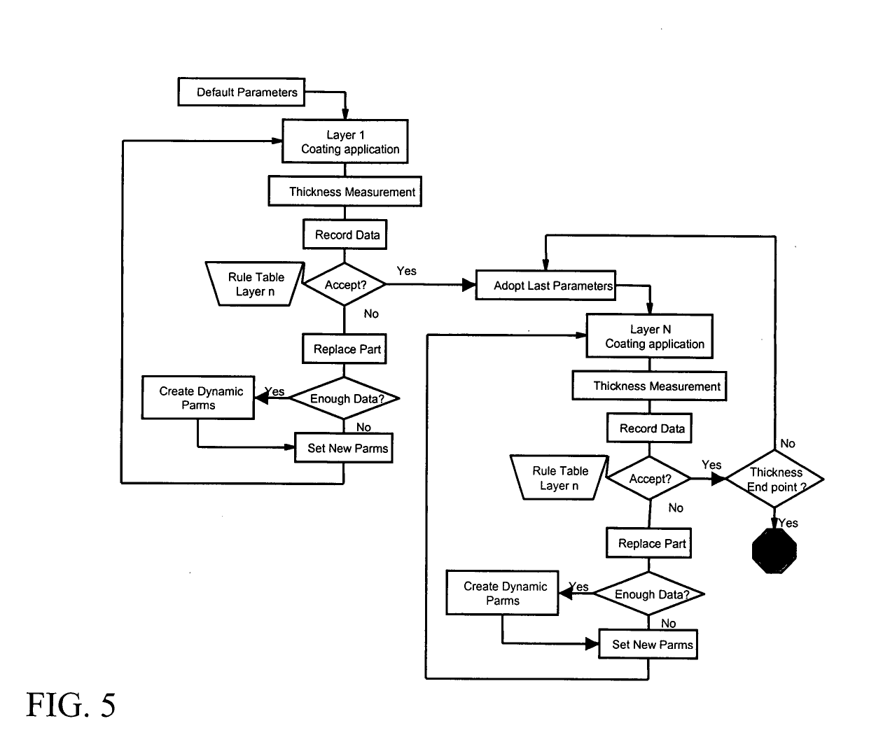

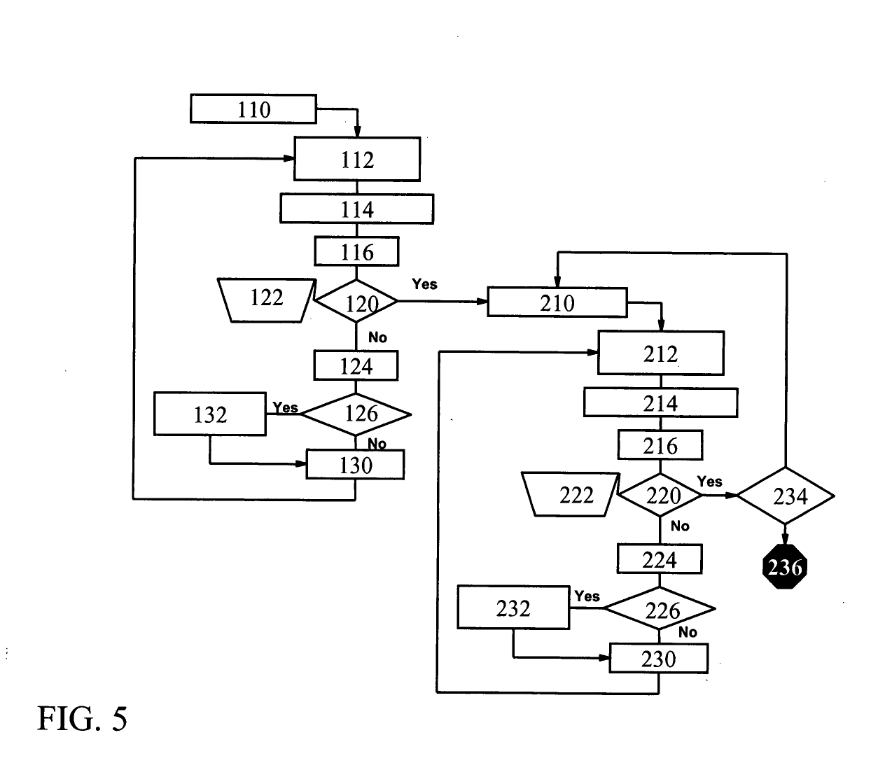

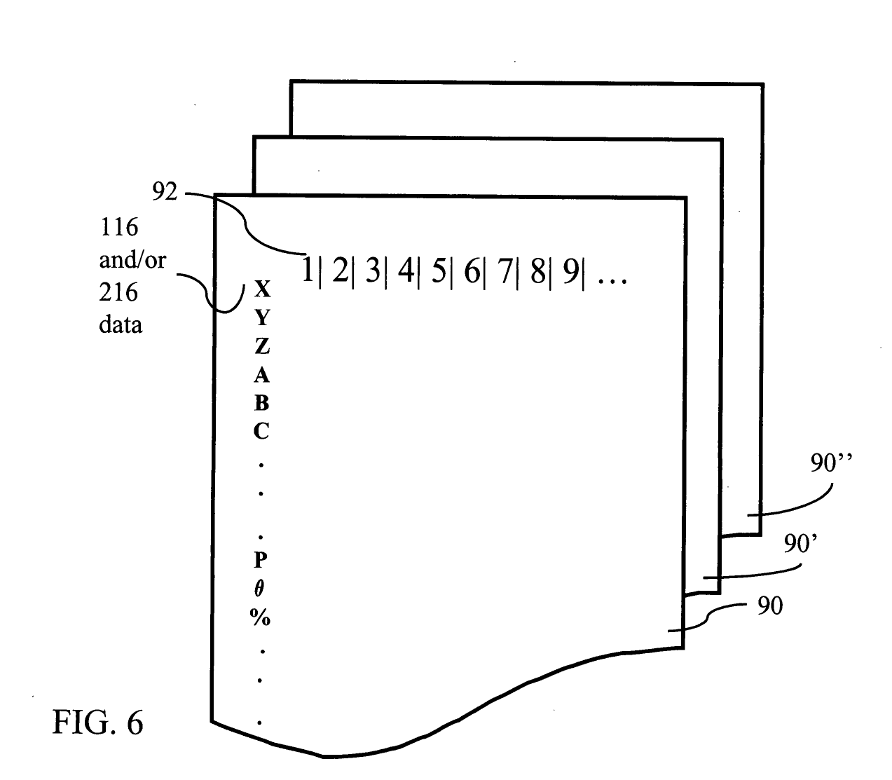

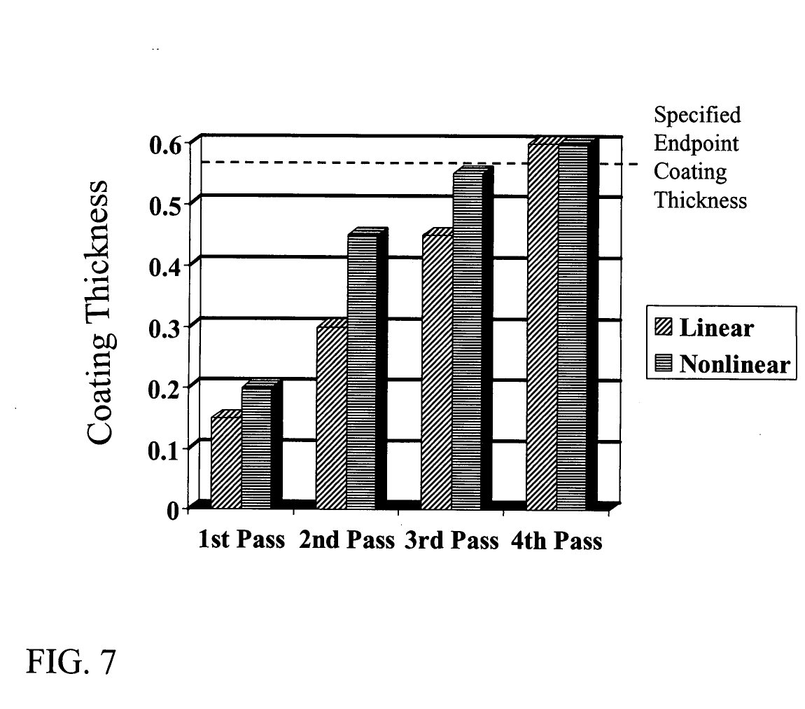

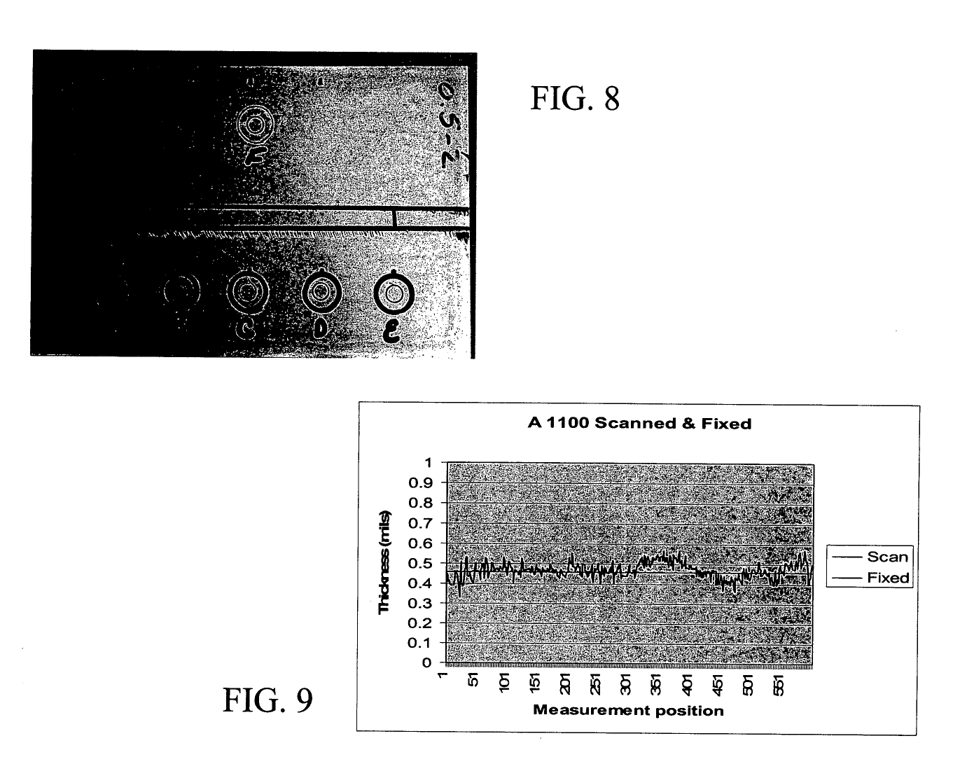

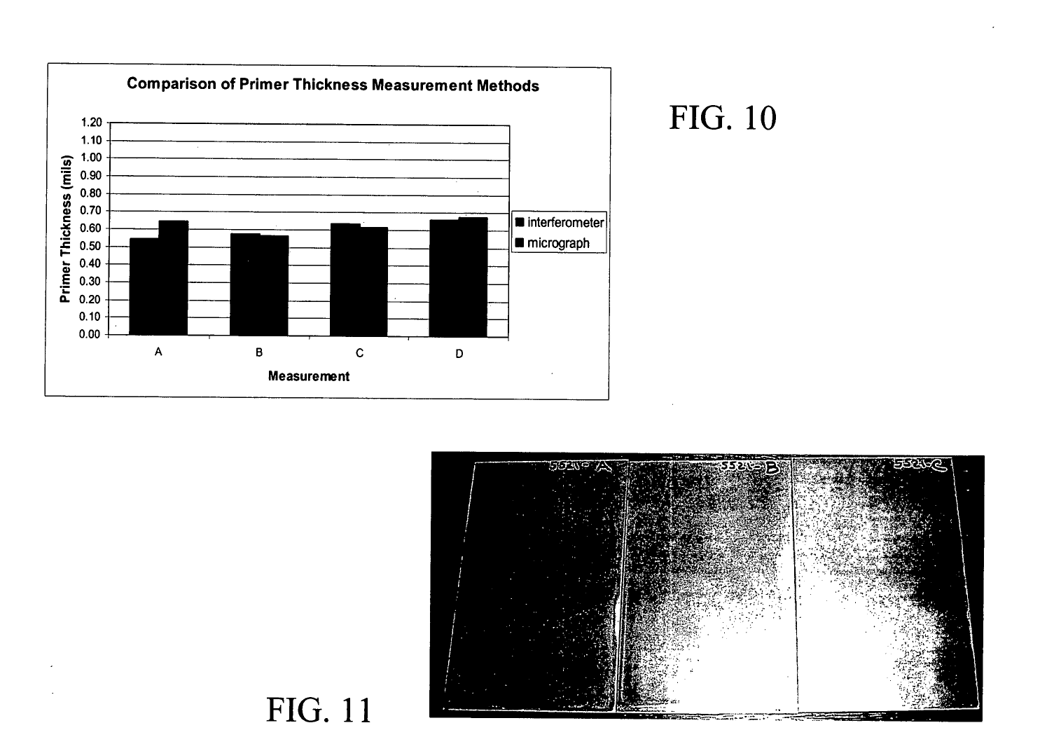

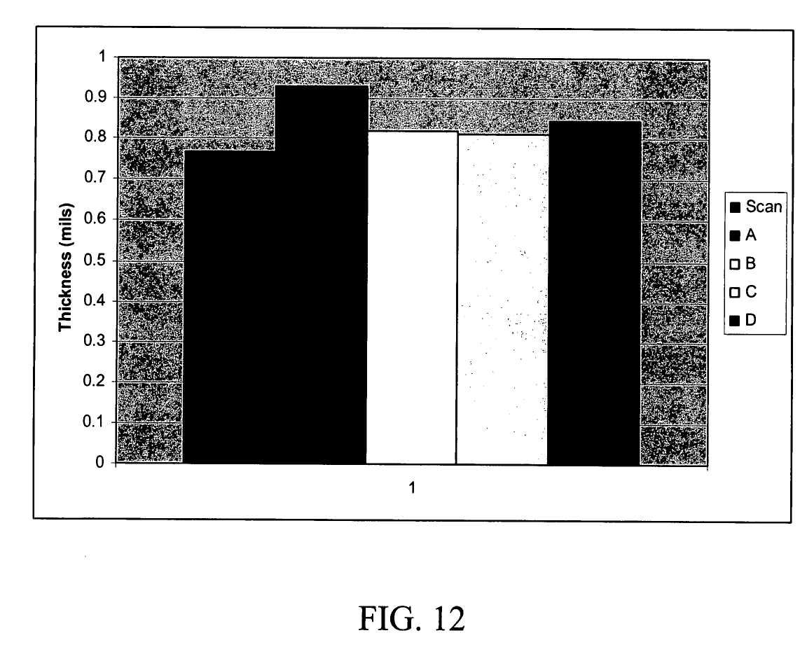

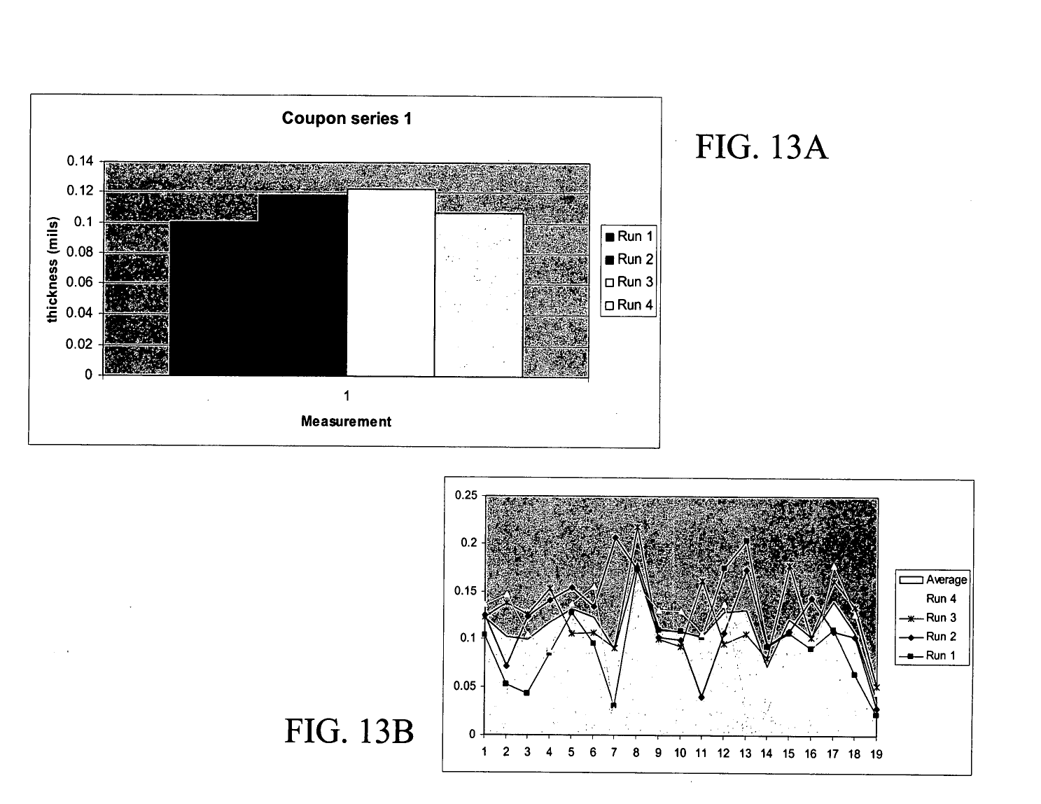

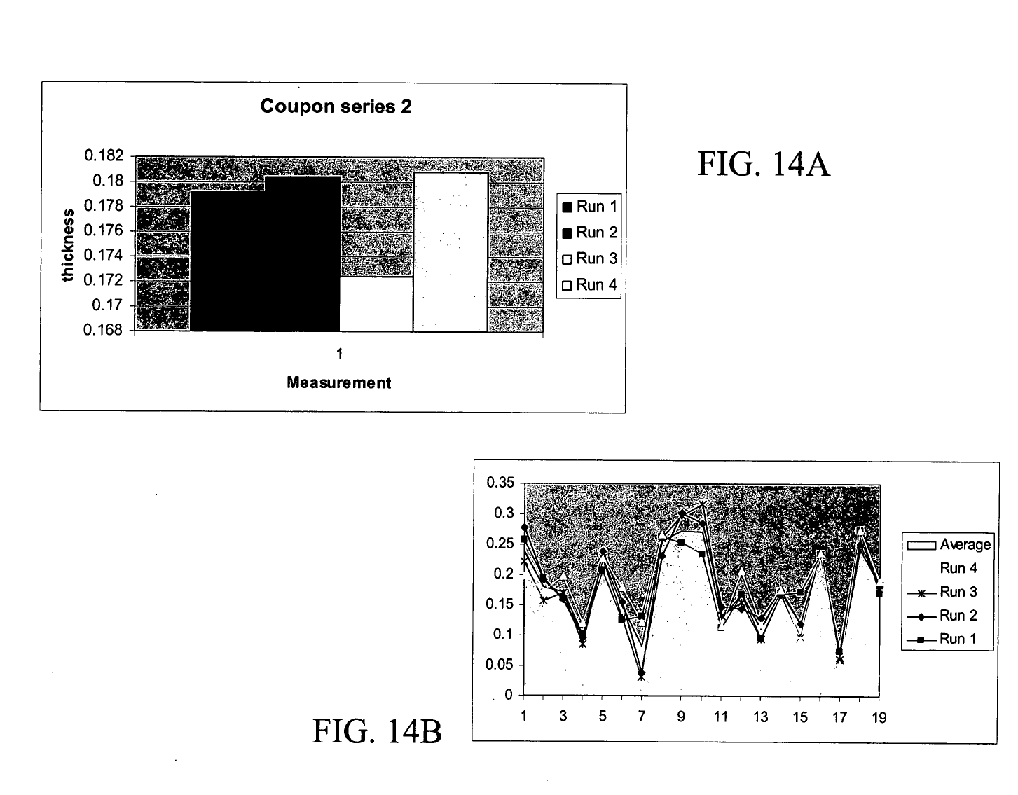

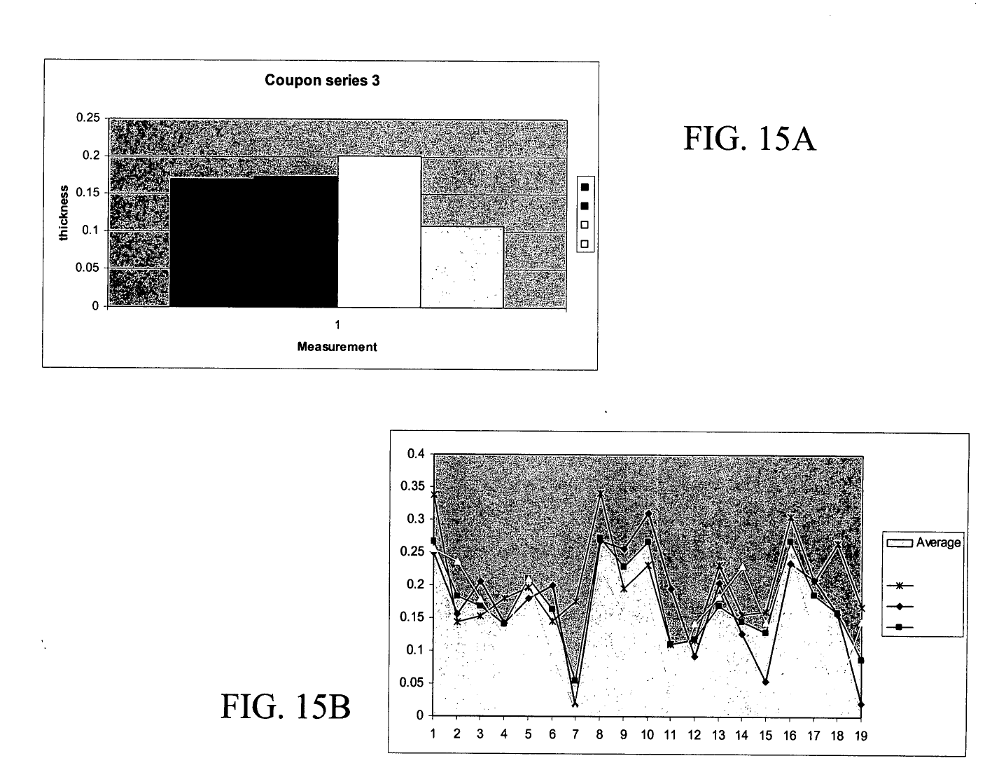

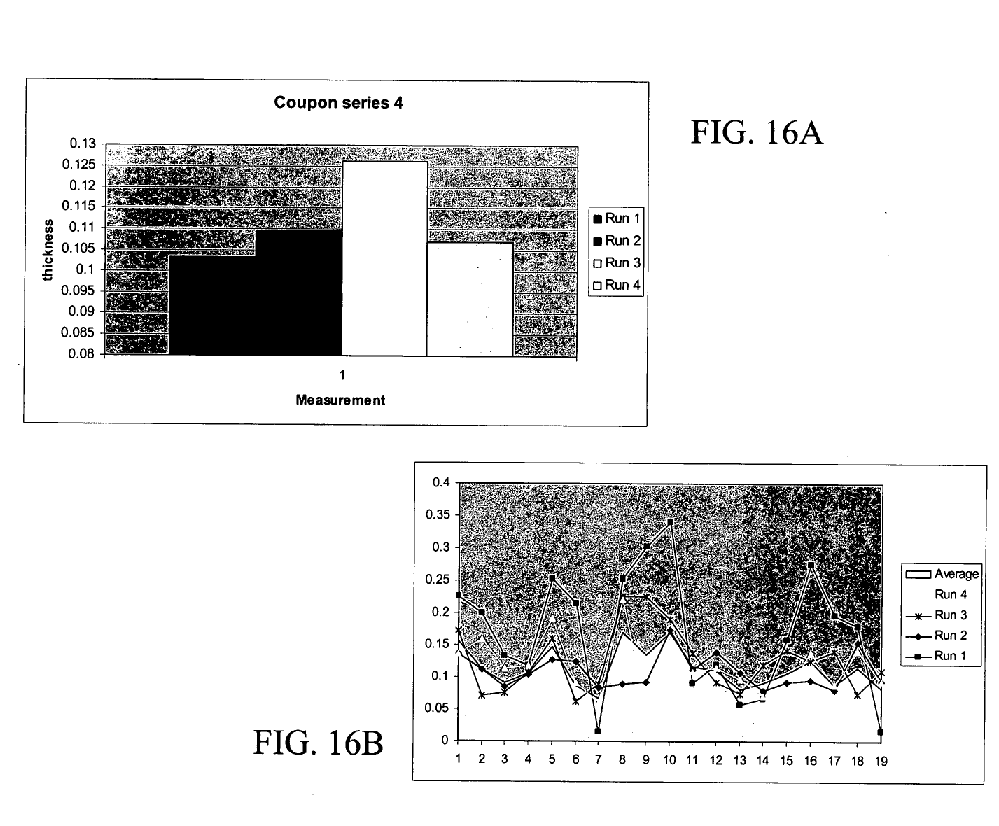

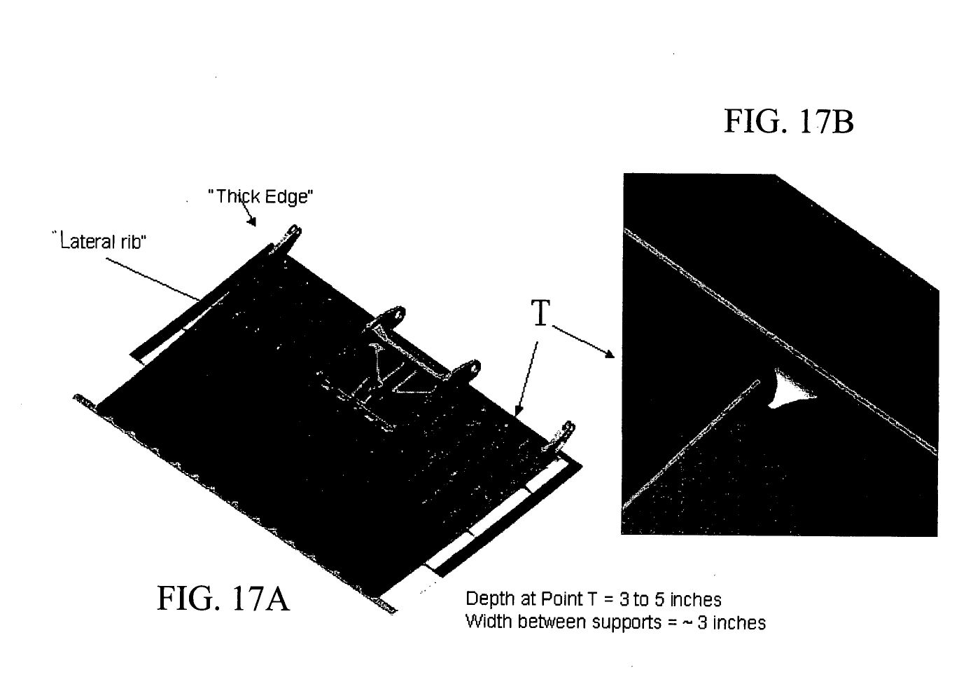

The thickness monitor 12 communicates with a probe 14 via a monitor coupling 16. The coating applicator 20 communicates with an applicator 22 via an applicator coupling 24. The multiple-axis device 26 may be used to move either a substrate 60 (as illustrated in FIG. 3A such an arrangement may be beneficial in that the applicator 20 may be spatially separated from the probe 14) and/or a probe 14 and an applicator 22, either together (as illustrated in FIG. 3B, such an arrangement may be beneficial in that the applicator 20 and the probe 14 may be operated substantially simultaneously) or individually (as illustrated in FIG. 3C, such an arrangement may be beneficial in that the applicator 20 may be spatially separated from the probe 14). When the probe 14 is used in the vicinity of or in combination with the applicator 22, it is beneficial for the probe 14 to include some type of shielding to protect aspects of the probe 14 that might otherwise become fouled or inoperative from the applied coating materials.

A variety of techniques might be used to measure a product thickness according to the present invention including, for example, interference, scattering, absorption, absorption, magnetic techniques eddy current and the like. Two techniques that appear well suited are interferometry and combinations of eddy current and capacitive sensing.

FIG. 4 is a schematic of an incident radiation 66 directed at a substrate 60 including a first coating 62 and a second coating 64. At an atmosphere/second coating interface 70, a portion of the incident radiation 66 is reflected as reflected radiation 80. The non-reflected portion of the incident radiation 66′ may be refracted (due to a difference in the refraction index of the atmosphere and second coating 64) to continue along a path through second coating 64 to second coating/first coating interface 72. Upon reaching the second coating/first coating interface 72, again, a portion of that incident radiation 66′ is reflected as a reflected radiation 82′ that may eventually emerge from the second coating 64 as reflected/refracted radiation 82. A final portion of a non-reflected radiation 66″ continues to travel to the first coating/substrate interface 74, and a portion is absorbed by the substrate 60, while another portion is reflected as reflected 84″ to become reflected/refracted radiation 84′ that may eventually emerge from the second coating 64 as reflected/double refracted radiation 84.

The intensity and wavelength of the reflected radiation 80, reflected/refracted radiation 82, and reflected/double refracted radiation 84 provide information that can be processed using interferometry. The information may be manipulated using fast Fourier transform (FFT) method to measure or determine the thicknesses of layers 62 and 64. It is noteworthy that using this FFT technique has a capability of differentiating coatings having thicknesses differing by orders of magnitude. For example, a substrate 60 made of an anodized layer ranging from about 200 nanometers to about 1000 nanometers can be distinguished from an organic coating added thereto having a thickness from about 1 micrometer to about 100 micrometers.

FIG. 5 depicts a controller block diagram useable with teaching an intelligent coating system 10 as depicted in FIG. 1 and FIG. 2 according to an aspect of the present invention. The teaching of the an intelligent coating system 10 may include known methods including, for example, those discussed in “Introduction to Machine Learning (Draft of Incomplete Notes)” by Nils J. Nilsson, Artificial Intelligence Laboratory, Department of Computer Science, Stanford University, Stanford, Calif. 94305 (available online at http://robotics.stanford.edu/people/nilsson/mlbook.html) the disclosure of which is herein incorporated by reference. After a substrate 60 is positioned, a training of an intelligent coating system 10 is begun at Step 110.

Step 110: Set default parameters for initiating the training of the intelligent coating system 10 (these parameter may be either manually entered and based on a best guess or selected from a previously developed set of parameters developed by coating a similarly shaped substrate 60).

Step 112: Apply a first layer of product (Layer 1).

Step 114: Measure the thickness of the product created on the substrate 60 by applying a first layer of product (Layer 1).

Step 116: Record the data relating to the product created on the substrate 60 by applying a first layer of product (Layer 1) including a product thickness and the corresponding applicator 22 coordinates (e.g., X, Y, Z, A, B, C), probe 14 coordinates (e.g., X′, Y′, Z′, A′, B′, C′), applicator 22 parameters {e.g., υ (velocity), α (acceleration), θ (applicator 22 spray angle), P (applicator 22 pressure), Δ (applicator 22 spacing or spraying density), v % (applicator 22 coating percent solids), p/c (applicator 22 propellant/coating ratio), [symbol] (applicator 22 coating flowrate), T (application temperature), v (applicator 22 coating viscosity), Ts (substrate temperature), Ta (ambient temperature), RHa (ambient relative humidity) . . . etc.}

Step 120: Determine whether the product thickness is acceptable with respect to prescribed thickness and prescribed thicknesses distribution over the substrate 60 as may be set out on the Rule Table 122. If the thickness is unacceptable, go to Step 124, replace the part. If it is acceptable at that point, go to Step 210.

Step 124: Replace the part.

Step 126: Determine whether there is sufficient data for developing dynamic coating parameters. If not, go to Step 130, set new parameters (as with Step 110, these parameters may be either manually entered and based on a second best guess or selected from another previously developed set of parameters developed by coating a similarly shaped substrate 60). These parameters may be a systematic change to the default parameters of Step 110 to building up data matrices 90 for use in Step 132.

Step 130: Set new parameters (as with Step 110, these parameter may be either manually entered and based on a second best guess or selected from another previously developed set of parameters developed by coating a similarly shaped substrate 60). These parameters may be a systematic change to the default parameters of Step 110 to building up data matrices 90 for use in Step 132. Then loop back to Step 112.

Step 132: Determine dynamic parameters based on data matrices 90 from earlier runs and a prescribed algorithm.

Step 210: Adapt last parameters from previous coating layer (Layer N-1).

Step 212: Apply a subsequent layer of product (Layer N).

Step 214: Measure the thickness of the product created on the substrate 60 by applying a subsequent layer of product (Layer N).

Step 216: Record the data relating to the product created on the substrate 60 by applying a subsequent layer of product (Layer N) including a product thickness and the corresponding applicator 22 coordinates (e.g., X, Y, Z, A, B, C), probe 14 coordinates (e.g., X′, Y′, Z′, A′, B′, C′), applicator 22 parameters {e.g., υ (velocity), α (acceleration), θ (applicator 22 spray angle), P (applicator 22 pressure), Δ (applicator 22 spacing or spraying density), v % (applicator 22 coating percent solids), p/c (applicator 22 propellant/coating ratio), [symbol] (applicator 22 coating flowrate), T (application temperature), v (applicator 22 coating viscosity), Ts (substrate temperature), Ta (ambient temperature), RHa (ambient relative humidity) . . . etc.}.

Step 220: Determine whether the product thickness is acceptable with respect to prescribed product thickness, prescribed subsequent layer (Layer N) thickness, prescribed product thicknesses distribution over the substrate 60, and prescribed subsequent layer (Layer N) thickness distribution over the substrate 60 as may be set out on the Rule Table 222. If the thickness is unacceptable, go to Step 224 and replace the part. If it is acceptable, go to Step 234.

Step 224: Replace the part.

Step 226: Determine whether there is sufficient data for developing dynamic coating parameters. If not, go to Step 130 and set new parameters (as with Step 110, these parameters may be either manually entered and based on a second best guess or selected from another previously developed set of parameters developed by coating a similarly shaped substrate 60). These parameters may be a systematic change to the default parameters of Step 110 to building up data matrices 90 for use in Step 232. If not, go to Step 230.

Step 230: Set new parameters (these parameter may be either manually entered and based on a best guess or selected from another previously developed set of parameters developed by coating a similarly shaped substrate 60). These parameters may be a systematic change to the adapted last parameters from previous coating layer (Layer N-1) of Step 210 to building up data matrices 90 for use in Step 232. Then loop back to Step 212.

Step 232: Determine dynamic parameters based on data matrices 90 from earlier runs for subsequent layer of product (Layer N) and a prescribed algorithm.

Step 234: Determine whether the total thickness of the product is at the end point. If it is not, then run through another coating process by going back to Step 210. If it is, then go to Step 236 and stop the process.

Step 236: Stop the process.

The controller block diagram charted in FIG. 5 serves to teach an intelligent coating system 10 at least two aspects. A first aspect is an acceptable coating process for forming a product, which may comprise a plurality of layers, on a substrate 60 having either simple or complex shape that conforms with the rule table 122 such that the product has a prescribed thickness distribution over the substrate 60. This can be useful in some aviation applications using an anodized aluminum substrate 60. In such a case, when the product thickness is insufficient, corrosion of the aluminum substrate 60 may occur. In situations where the thickness is too great, the product might break off to create a weak body.

One advantage of an intelligent coating system 10 is that it may be used with a substrate 60 having a complexly configured surface. As illustrated on both in FIG. 1 and FIG. 2, a complexly configured surface may include any one of crevices, ridges, blind holes, and combinations thereof. Such characteristics may be used advantageously for applications where a uniform product thickness over the complexly configured surface is desired. One such application includes anodized aluminum aviation components. In such components, an anodized coating is formed on the aluminum components to enhance corrosion resistance. However, an anodized coating may include crevices, and by being a ceramic, can be brittle. By applying an epoxy-based product to an anodized aluminum aviation component, cracks and crevices can be sealed. In addition, a product may be used to place the anodized layer in a state of residual compressive stress.

Further, the operation of the algorithm in FIG. 5 allows for teaching intelligent coating system 10 to create (1) a prescribed product thickness distribution over a substrate 60 for a given layer and (2) a prescribed product thickness distribution over a substrate 60 by multiple applications of individual layers.

The data recorded in Step 116 and Step 216 might be represented as a data matrix 90 such as that illustrated in FIG. 6. Each data matrix 90 of a plurality of data matrices might be designated data matrix 90, data matrix 90′, data matrix 90′″, and so forth. Each data matrix 90 might relate to the spatial relationship of the substrate 60, as well as the operating parameters such as a product thickness and the corresponding applicator 22 coordinates (e.g., X, Y, Z, A, B, C), probe 14 coordinates (e.g., X′, Y′, Z′, A′, B′, C′), applicator 22 parameters {e.g., υ (velocity), α (acceleration), θ (applicator 22 spray angle), P (applicator 22 pressure), Δ (applicator 22 spacing or spraying density), v % (applicator 22 coating percent solids), p/c (applicator 22 propellant/coating ratio), [symbol] (applicator 22 coating flowrate), T (application temperature), v (applicator 22 coating viscosity) ), Ts (substrate temperature), Ta (ambient temperature), RHa (ambient relative humidity) . . . etc.}. Such data can be associated with a data set 92 that might be represented as a column assigned, for example, a number. As the coordinates of the applicator 22 and the probe 14 may be spatially related, a plurality of location information might be kept in a data matrix 90. Alternatively, an algorithm may be used to transform or map the location of the applicator 22 relative to the probe 14, or there can be specific data for each device kept in a data matrix 90.

Once a sufficient number of results or data (e.g., data matrices) have been obtained, the data may be manipulated as by means of, for example, a splining algorithm to come up with a dynamic control of the applicator 22 to provide a corresponding prescribed thickness application. This data from multiple runs may be used to provide a uniform distribution of product over the entire body. In turn, if it is desirable to build up a product using a plurality of layers to a prescribed end point thickness, this may also be accomplished.

FIG. 7 shows examples of product thickness build-up by linear and nonlinear multiple passes coating of a substrate 60. Here, the coating thickness specification is shown to have an end-point thickness somewhere between 0.5 and 0.6 (an arbitrary scale). In one operation, the product thickness build-up by multiple passes is a linear build-up. In such case, the thickness of the product is built up by similar amounts of thickness for each pass. Alternatively, it may be that the build-up is non-linear.

Returning to FIG. 1 and FIG. 2, the thickness monitor 20 includes at least one radiation source, a probe 14 for capturing radiation reflected and/or refracted from the substrate 60 and through the product layers 64, 62, and a detector that is coupled to the probe 14. The detector deconvolutes the spectrum of the captured reflected and/or refracted radiation to determine the coating thickness.

In FIG. 2, the probe 14 is shown to be adjacent to the applicator 22. However, Applicant contemplates that the probe 14 may be separated from the applicator 22, as shown in FIG. 3A and FIG. 3C. It is advantageous for probe 14 to move over the surface of the substrate 60 without contacting the surface to not be altered or damaged the product layers 64, 62 during the thickness determination.

After coating, a probe 14 is used for measuring the thickness of the product layers 64, 62. In an aspect of the present invention, a probe 14 remains stationary as an anodized substrate 60 moves by, thereby measuring a thickness along a length of the product. In another aspect of the present invention, a probe 14 also moves substantially perpendicular to the direction of the movement of an substrate 60, thereby measuring a thickness along an area of the substrate. In this manner, a product thickness distribution over the surface of a product such as a sheet, coil, or foil may be determined. As best seen in FIG. 3C, a robotic arm may be used to move a probe 14 across a substrate 60 having product layers 64, 62 to determine the product thickness at a select point, a select region, or even over the entire surface of a substrate 60. More details concerning motion control and robotics are discussed in, for example, U.S. Pat. Nos. 5,872,892; 4,979,093; 4,835,710; 4,417,845; 4,352,620; and 4,068,156, the entire disclosure of each being incorporated by reference herein.

A thickness monitor 20 includes at least one radiation source, a probe 14 for capturing the reflected and/or refracted radiation, and a detector for measuring or deconvoluting the spectrum of the reflected and/or refracted radiation.

A radiation source may be polychromatic, for example, ultraviolet (UV), visible, infrared (IR), or monochromatic. A radiation source that is polychromatic may be a subset of any of UV (having wavelengths in the range of about 4 to about 400 nanometers), visible (having radiation wavelengths to which the organs of sight react, ranging from about 400 to about 700 nanometers), and IR (having wavelengths between 750 nanometers and 1 millimeter). Examples of such subsets include vacuum ultraviolet radiation (UV radiation having wavelengths less than about 200 nanometers; so-called because at shorter wavelengths the radiation is strongly absorbed by most gases), far-ultraviolet radiation (the short-wavelength region of the UV range: about 50 to about 200 nanometers), near-ultraviolet radiation (ultraviolet radiation having wavelengths in the range of about 300 to 400 nanometers), far-infrared radiation (long-wavelength region of the infrared range: about 50 to about 1000 micrometers) and near-infrared radiation (radiation having wavelengths in the range of about 0.75 to about 2.5 micrometers). Alternatively, a radiation source may be monochromatic.

In an embodiment, a thickness monitor 20 includes an additional radiation source. The radiation source and additional radiation source may be any one of polychromatic and monochromatic and are selected to complement each other to improve, for example, the intensity and breadth of reflected radiation available for determining the thickness of a product layers 64, 62 on a substrate 60. Typically, a single radiation source has an intensity that is greatest in a central range but decreasing on either end. By complementing this with an additional source of radiation, there can be an overlap of the decreasing intensities to remove them. In this way, several advantages may be realized. For example, there may be an increase of signal to noise ratio with respect to the reflected radiation. Also, there may be an increase in the range of reflected radiation that can be captured. In this way, the other aspects of a coating's properties may be determined.

As seen in FIG. 1 and FIG. 2, the probe 14 for capturing the reflected and/or refracted radiation, includes a monitor coupling 16 for delivering the radiation back to the detector. The probe 14 for capturing and directing the reflected and/or refracted radiation back to the detector may include a collimator. The collimator may be used to direct the captured reflected radiation into the coupler that directs the radiation to the detector.

The detector is the type that demodulates the reflected spectrum once it is received. Examples of equipment that might be used with this are included in, for example, U.S. Pat. Nos. 6,052,191; 5,999,262; 5,289,266; 4,748,329; 4,756,619; 4,802,763; 4,872,755; and 4,919,535, the entire disclosure of each being incorporated by reference herein. Part of determining the coating thickness is through demodulating the reflected spectrum. Various techniques are known for measuring this including color interference method, absorption method, ratio of the intensity of the maximum wavelength to the intensity of the minimum wavelength, and the fast Fourier transform (FFT) method (e.g., the processing of a signal generated by waves striking a detector, whereby the signal is transformed into a digital time series for spectrum analysis). More details concerning single and multiple coating thickness determination are discussed in, for example, U.S. Pat. Nos. 6,674,533; 6,128,081; 6,052,191; 5,452,953, 5,365,340; 5,337,150; 5,291,269; 5,042,949; 4,984,894; 4,645,349; 4,555,767; and 4,014,758, the entire disclosure of each being incorporated by reference herein.

A thickness detector includes a monitor coupling 16. The monitor coupling 16 acts to direct the reflected radiation from the probe 14 to the detector. The monitor coupling 16 may also act to provide the source radiation to the surface of the substrate 60 through the probe 14. Alternatively, a radiation source may be integral to the probe 14 to provide the source radiation to capture the reflected radiation from the substrate 60, having product layers 64, 62. A monitor coupling 16 may be a fiber optic guide that includes a plurality of fibers arranged in a manner to capture the radiation optimally, having a composition that transmits the reflected radiation without attenuation. The monitor coupling 16 may include multiple components. In an aspect, the monitor coupling 16 communicates with the radiation source to direct radiation to the surface of the substrate 60, as well as communicating with the detector to direct the reflected and/or refracted radiation to the detector for analysis. Monitor coupling 16 may include multiple sets of fibers when the thickness monitor 12 includes multiple radiation sources and multiple detectors. The configuration and composition of optical fiber bundles are selected to optimally transmit the radiation interest.

As seen in FIG. 1 and FIG. 2, the intelligent coating system 10 may include a controller 30 that may be, for example, a computer. The intelligent coating system 10 may operate without the computer or an intermediate box to communicate with the controller 30. More details concerning controllers that may be used in the intelligent coating system 10 are discussed in, for example, U.S. Pat. Nos. 5,980,078; 5,726,912; 5,689,415; 5,579,218; 5,351,200; 4,916,600; 4,646,223; 4,344,127; and 4,396,976, the entire disclosure of each being incorporated by reference herein.

In this regard, with reference to FIG. 1, a controller 30 in combination with the thickness monitor 20 may be used as an endpoint determiner in the intelligent coating system 10. During coating, the process parameters may be controlled while allowing an operator to know, in real time, the thickness of the product layers 64, 62. At a time that the product layers 64, 62 grow to a desired endpoint thickness on the substrate 60, the process shuts down. Clearly, this ability to know the coating thickness as it grows is advantageous over any method where the substrate 60 is removed from a coating system, its coating thickness determined and then replaced into the coating system.

A benefit of the present invention is the ability to produce a product on a substrate 60 having a better quality and consistency from batch to batch, both linear and areal, over the length and surface better than a product made without an intelligent coating system 10 of the present invention.

Protective coatings are used to prevent oxidation and corrosion of the aluminum and its alloys in numerous applications, such as in the aircraft industry. In many applications, after anodizing, additional barrier coatings may be added to promote adhesion of additional coatings, typically of an organic nature, such as epoxies, resins, composite coating components, and top coats (e.g., paint and decals).

The thickness of an anodized coating and further coating is measured using the thickness monitor 20 of the present invention that operates using interferometry that is independent of substrate thickness. In this way, the thickness monitor 20 is non-contact, non-destructive, fast, robust, and reliable. Also, the thickness monitor 20 may facilitate simultaneous thickness measurement of an anodized coating and further coating. The use of a guide(s) based on fiber optic technology provides intrinsic isolation of the thickness monitor 20 from the process. Also, in situ measurement inside the anodized bath or at strategic inspection points may be simplified.

In a test of the thickness monitor 20 of the present invention, the radiation source was coherent white light provided to a coated substrate by a multiple guide optical coupler composed of a plurality of optical fibers. A first guide illuminated the coated substrate surface, and a second guide captured and transmitted the reflected light to a detector. One end of the guide system combines the two guides and is coupled to the coated substrate by collating lenses. The opposite end of the guide system diverges to the radiation source of the detector. The composite reflection is transmitted to the detector, which on this embodiment is a spectrometer. The interference within the composite reflection is superimposed onto the reflection signal. Fast Fourier Transformation (FFT) analysis is used to determine the thickness. The parametric set-up allows the thickness monitor 20 to be configured to various coating types.

Equipment used in a coating thickness monitor according to the present invention include a spectrometer (Model DSPec/1024/6 having a DSP-based spectrometer with an about 1024 element detector available from Analytical Technologies, L.L.C., Morganton, N.C.); a radiation source (Model HALXE 50 having a composite halogen/Xenon spectral lamp, with shutter available from Analytical Technologies, L.L.C., Morganton, N.C.); a guide system including a plurality of optical fibers (Model 6/1/SMA/FS made from fused silica with 6 detectors around 1 illuminator in SMA terminal, available from Analytical Technologies, L.L.C., Morganton, N.C.); and a probe (Model 50/5/SMA including a tube-mounted lens with an about 50 mm focal distance, an about 5 mm spot size SMA terminal, available from Analytical Technologies, L.L.C., Morganton, N.C.).

This equipment was interfaced with a personal computer (PC) running a program entitled FTM ProVIS software available from Dip1.-Ing. (FH) Thomas Fuchs, Ingenieurburo fur Angewandte Spektrometrie, Roentgenstr. 33-D-73431 Aalen-Germany.

The interference of two light rays may be described with the following simplified formula:
I(1)=A+B*cos [2p*Dr/1+Dd],

where:

I(1) is an interference intensity for wavelength 1;

A contains the intensity of the two light rays;

B is an amplitude of the cosine function;

1 is a wavelength;

Dr is an optical path difference (thickness); and

Dd is a phase shift of the two light rays.

The optical path difference “Dr” itself is the product of the required geometric thickness “d” and the refractive index “n”: Dr=2 n(1)*d. Generally, the refractive index “n” is a function of the wavelength “1”, which is described as “dispersion” (see below), and in the present case was assumed to be about 1.4789 for alumina.

In the FTM ProVIS software, the required geometric thickness “d” is calculated by the determination of the interference function shown above (the expression “Dr/1” corresponds to a frequency function). This frequency was determined with the help of a “Fast Fourier Transformation” (in shortened form: FFT). In the reciprocal representation of the interference spectrum, the peak position of the Fourier-transformed interference (the Fourier-spectrum, or short: FFT-spectrum), with known dispersion “n(1)”, directly supplies the film thickness. The FTM ProVIS software may take into account the dispersion by using a polynomial formula, following the dispersion formula according to Cauchy (dispersion correction):
n(1)=n+B/1²+C/(1²*1²),

where:

n(1) is the dispersion of a wavelength 1;

n is a polynomial constant;

B and C are polynomial factors; and

1 is a wavelength.

### EXAMPLE

An optical thickness gauge for Non Destructive Testing (NDT) of spray coatings applied to aerostructures was tested. The test illustrates the benefits of integrated real time thickness control for a robotic spray process. It can be useful when applying an epoxy-based coating on a complex shape such as a spoiler made from a machined aluminum surface such as “gridlock.”

For this study, thickness values are determined by interferometry and reported directly by the instrumentation in microns (1*10⁻⁶ meters). Data were imported into MS Excel. Supporting spreadsheet calculations provide refractive index corrections and conversion from microns to mils (1/25.4). Samples used in this study were bare 7075 alloy.

The optical thickness control system uses light as a measurement medium. Light provides intrinsically safe, non-contact measurement of optically transparent films based on an interference technique and is delivered to the sample surface by a fiber optic system, which insures stable and robust operation even in harsh environments.

Interference occurs as refracted light from the inner border of the coating is returned to the surface slightly out of phase with the first surface reflection. A spectrometer is used to detect constructive and destructive reflections from the surface of the sample at specific wavelength bands in the spectrum where the coating is transparent.

Instrument Validation:

The measuring system was first validated using a destructive test. This was required because the optical border conditions between the anodization layer and coating may be nebulous in nature.

Optical thickness results are influenced by the refractive index of the measured layer(s). Results are indirectly skewed by the index value so the initial set-up of the instrument utilized no correction or a factor of 1. The thickness of four points A-C for the sample of FIG. 8 using a destructive technique requires cross-sectioning the sample and measuring by a photo micro-graph technique.

The hardware is configured in modules so that it can be easily integrated into an existing spray coating system with minimal effort. It offers straightforward operation as a fixed point test bench or in mobile, hand operated modes. A separate process interface couples any positioning device to the measurement to provide high level and intelligent interaction with a process controller or PLC.

Coating thickness variation was significantly high enough to justify the need for multiple measurements over each area A-C. Results for each spot contain 25 individual discrete measurements over the inner circles. The average and standard deviation of each measurement is provided for comparison to the micro-graph data. A scanned area was compared to a fixed-point measurement (see FIG. 9) to eliminate the instrument as a source of significant error.

An index value of 1.70 for the coating was empirically determined. A comparison of the two techniques is illustrated in FIG. 10.

Three test panels A, B, and C (see FIG. 11) were used for validation of the measurement data representing high, control, and low limits. Four specific locations were measured on each coupon and identified accordingly; i.e.,. A.1. A.2 . . . A.4.

An area of each coupon was scanned by acquiring data from 100 measurements across the length of the panel to illustrate variation within the sample. The scanned thickness data was compared once with fixed point data to demonstrate fixed point accuracy of the system and demonstrate precision of the instrument. FIG. 12 illustrates the importance of collecting an adequate amount of data. The measuring speed of the system simplifies collection of high-density measurement. This allows a better understanding of the process and the potential weight addition or loss the coating provides to a larger structure.

The next test included 20 coupons specifically placed at locations on a detail that represent boundary conditions of the spray process. The purpose is to measure the coating thickness of each layer applied to the detail. The experiment also shows the variability of coating at specific locations and the variation across some coupons which contain a thickness gradient. In this case, a method can be applied to control both thickness and flow rate of the coating applicator with the goal of consistent coating thickness and weight.

Measuring bond primer thickness automatically is beneficial in collecting data so that the thickness can be validated with minimal labor impact. The flow rate of the coating system may require adjustment to compensate for restrictions in airflow in gridlock type material. Standing waves and a vortex may occur in the pockets and cause variations in the thickness. So it is important to know how thick the coating is at strategic locations in order to adjust flow to compensate for this type of surface condition.

Dynamic correction is of great benefit especially in start-up mode where the coating process may not have reached equilibrium. So using a thickness gauging technique, which is integrated into the robotic spray applicator, is very important to guarantee compliance.

One measurement series contains measurement data for 19 coupons which were placed at various locations on the spoiler detail. Placement of these details was determined by the robot operator. Four separate runs were performed using different conditions.

Due to the measurement area of interest (AOI) for the instrument, each sample was measured four times and data averaged to gain a better understanding of the information presented by the instrument. Data presented in FIGS. 13A, 13B, 14A, 14B, 15A, 15B, 16A, and 16B contain four trends per chart and an average to summarize each run. Each run contains four measurements for each coupon.

Run Summary

Overall average thickness per run will illustrate robot applicator flow rate or scan speed changes and the variation in measurement within each run.

Average thickness per coupon shows how thickness varied in each coupon/location and how uniformity of the coating changes with respect to process changes.

Coupon Thickness:

FIGS. 13A, 13B, 14A, 14B, 15A, 15B, 16A, and 16B show how each location is influenced by spray changes and identifies some specific locations where thickness limits may be exceeds in normal production.

Benefits of this Approach:

In general, adequate coating thickness is required for proper coverage and can be guaranteed only by measuring the coating during or immediately following spray applications. The optimum thickness of a coating may require several spray applications to insure that each layer cures (dries) properly after each application. In this case, the measurement of each layer's application allows the correct film build to occur. Optimal drying can be measured as the coatings liquid evaporates, indicative of a decrease in film thickness between application and drying. Therefore, it can be assumed that the evaporation is in equilibrium when thickness change becomes constant, at which point it is safe to apply another coating layer.

The optical measurement technique provides non-contact measurement even in small bond positions where adhesives are applied, such as rib and ridges. The spot sizes can be adjusted to accommodate different stand-off requirements. The optical method is also superior to other methods because it is able to measure abstract shapes which will distort both electro-magnetic and electrostatic fields. No special preparation or handling is required, so it is suitable for measuring both wet and dry specimens. The technique offers relatively high stand-off, so it can be positioned with a robot or even with a fixed-point stage.

The optical measurement technique also insures a high degree of safety and allows the system to be used in solvent applications with no risk or added regulatory burdens. The measuring speed of the system provides immediate process information needed to insure adequate film-build rate and a better understanding of the coating and application process. The result is an increase in knowledge of the process.

Automatic positioning of the measuring head simplifies generation of a coating thickness profile (thickness difference with respect to position) which may develop as a result of standing waves generated by air flow patterns on abstract shaped parts (see appendix A). Also identified is a method for dynamically optimizing an automated spray application system using integrated film thickness measurement.

The charts show how thickness varied between specified measuring points on an abstract detail. A field test was performed using a reduced data set of 20 measurement positions. Each position is designed to represent a position on the detail where the coating application may be on the border of the spec limit.

An important point is that when integrated to a robotic positioning system, data are collected with virtually no labor. A high amount of information can be gathered quickly in real time shortly following a spray application to intuitively tune the process for each specific position.

The flow rate of the coating can be controlled dynamically based on coordinates of the spray applicator robots position in space. The method for optimizing the film thickness profile employs a dynamic adjustment of coating flow rate based on previously determined thickness data at specific points on a detail.

Notes:
A robot is a multi-axis device used to move the spray apparatus and/or probe.
The product may be a polymer or blend of polymers, metal particles encapsulated in a polymer carrier, ceramic particles contained in a polymer solution, or a petrochemical coating used to de-ice an aircraft.
The solution can be water or an organic solvent.
The layer is at least one application of a coating applied to the substrate.
The substrate is an anodized aluminum of any alloy combination or composite material. The substrate may be of an abstract shape as illustrated in FIG. 17.
Optimal drying time is determined by using this method to measure a decrease in film thickness. It can be performed in air or in a curing oven. The film is considered dry when the thickness change reaches a constant

Certain modifications and improvements will occur to those skilled in the art upon a reading of the foregoing description. By way of example, a real time process to control specified layer thickness for anodizing and a further coating of a substrate may be achieved based upon using an optical interference measurement technique employing monochromatic or polychromatic illumination or detection and an evaluation algorithm for determining thickness based upon FFT. Likewise, a statistical surface evaluation technique for layer thickness profiles using one or more axis of movement over any area of interest, either manually or automated multi-axis positioning system, may be suitable for use in a dip tank, or in an inspection booth. Further, the measurement on multiple surfaces (front, rear, or side) of flat piece goods may be achieved. A measurement mode on curved surfaces of irregular shape could also be achieved.

Also, appropriate measuring points on a parts rack could be achieved. This may be affected by aligning the optical sensors to achieve correct optical throughput and by positioning the measuring probe in various points on a sample part racks. Further, positioning the measuring probe on front, rear, or side of a part may be beneficial. Moreover, finding a statistical variation thickness would be helpful in process control and product quality and consistency. This might be affected by determining average thickness over a desired area of interest, determining the statistical variation in thickness over a desired area of interest, or determining thresholds of acceptability.

It should be understood that all such modifications and improvements have been deleted herein for the sake of conciseness and readability but are properly within the scope of the following claims.

| Item # | Term, Item # |
|---|---|
| 10 | intelligent coating system 10 |
| 12 | thickness monitor 12 |
| 14 | probe 14 |
| 16 | monitor coupling 16 |
| 18 | |
| 20 | coating applicator 20 |
| 22 | applicator 22 |
| 24 | applicator coupling 24 |
| 26 | multiple-axis device 26 |
| 28 | |
| 30 | controller 30 |
| 32 | input 32 |
| 34 | output 34 |
| 36 | databases 36 |
| 38 | |
| 40 | monitor/controller communication channel 40 |
| 42 | monitor/multiple-axis device communication channel 42 |
| 44 | applicator/multiple-axis device communication channel 44 |
| 46 | controller/multiple-axis device communication channel 46 |
| 48 | |
| 50 | monitor/applicator communication channel 50 |
| 52 | applicator/controller communication channel 52 |
| 54 | |
| 56 | |
| 58 | |
| 60 | substrate 60 |
| 62 | first coating 62 |
| 64 | second coating 64 |
| 66 | incident radiation 66 |
| 68 | |
| 70 | atmosphere/second coating interface 70 |
| 72 | second coating/first coating interface 72 |
| 74 | first coating/substrate interface 74 |
| 76 | |
| 78 | |
| 80 | reflected radiation 80 |
| 82 | reflected/refracted radiation 82 |
| 84 | reflected/double-refracted radiation 84 |
| 86 | |
| 88 | |
| 90 | data matrix 90 |

What is claimed is:

1. An intelligent coating system for forming a product on at least a portion of a substrate, the intelligent coating system including:
(a) a coating applicator;
(b) a thickness monitor for measuring the thickness of at least a portion of the product on the substrate formed by operation of the coating applicator, the thickness monitor including:
(i) at least one probe capable of communicating with at least a portion of the product on the substrate without contacting either, and
(ii) at least one detector in communication with the at least one probe, the at least one detector capable of processing the communication of the at least one probe with the at least a portion of the product to allow a determination of at least the thickness of the product on the substrate; and
(c) a multiple-axis device capable of facilitating a relative movement of at least a portion of the coating applicator and the substrate.

2. The intelligent coating system according to claim 1 further including at least one controller in communication with at least the thickness monitor.

3. The intelligent coating system according to claim 1 further including at least one controller in communication with at least the multiple-axis device, the coating applicator, and the thickness monitor.

4. The intelligent coating system according to claim 3 wherein the at least one controller regulates a relative movement of the probe and the substrate.

5. The intelligent coating system according to claim 3 wherein the at least one controller regulates at least one process parameter of the coating applicator.

6. The intelligent coating system according to claim 5 wherein the at least one process parameter includes at least one of:
(a) a rate of the relative movement of at least a portion of the coating applicator and the substrate;
(b) a distance between at least a portion of the coating applicator and the substrate;
(c) an angle between at least a portion of the coating applicator and the substrate;
(d) a coating application temperature;
(e) a coating application pressure;
(f) a coating application flowrate;
(g) a coating application coating/propellant ratio;
(h) a coating application solids content; and
(i) any combination thereof.

7. The intelligent coating system according to claim 3 wherein the at least one controller is capable of learning a process for providing a predetermined product thickness distribution over the substrate.

8. The intelligent coating system according to claim 3 wherein the at least one controller is capable of learning a process for providing a predetermined endpoint product thickness distribution over the substrate.

9. A thickness monitor for measuring the thickness of at least a portion of a product formed on at least a portion of a substrate in a coating system including a coating applicator and a multiple-axis device for facilitating a relative movement of at least a portion of the coating applicator and the substrate, the thickness monitor including:
(a) at least one radiation source capable of being directed at at least a portion of the product on the substrate,
(b) at least one probe capable of capturing at least a portion of the radiation reflected and refracted by the product on the substrate, the captured radiation being at least a portion of the radiation directed at the product on the substrate from the radiation source, and
(c) at least one detector in communication with the at least one probe, the at least one detector capable of processing the captured radiation to determine at least the thickness of the product on the coated substrate, where the thickness monitor is capable of converting the coating system into an intelligent coating system.

10. The thickness monitor according to claim 9 further including a coupling system.

11. The thickness monitor according to claim 10 wherein the coupling system is an optical couple.

12. The thickness monitor according to claim 11 wherein the optical couple is an optical fiber.

13. The thickness monitor according to claim 12 wherein the optical fiber is a plurality of optical fibers.

14. The thickness monitor according to claim 11 further including an additional coupling system capable of transmitting at least a portion of the radiation from the at least one radiation source to direct at least a portion of the radiation at at least a portion of the product on the substrate.

15. The thickness monitor according to claim 14 wherein the additional coupling system is an additional optical couple.

16. The thickness monitor according to claim 15 wherein the additional optical couple is an optical fiber.

17. The thickness monitor according to claim 16 wherein the additional optical fiber is a plurality of optical fibers.

18. The thickness monitor according to claim 13 further including a supplementary coupling system capable of at least one of:
(a) transmitting additional captured radiation from the at least one probe to the at least one detector;
(b) transmitting at least a portion of the radiation from at least one additional radiation source to direct at least a portion of the additional radiation at at least a portion of the product on the substrate; and
(c) transmitting at least a portion of the additional radiation from at least one additional radiation source to direct the at least a portion of the additional radiation at at least a portion of the product on the substrate and transmitting the additional captured radiation from the at least one probe to the at least one detector, the additional captured radiation being at least a portion of the additional radiation directed at the product on the substrate from the at least one additional radiation source.

19. The thickness monitor according to claim 18 wherein the supplementary coupling system is an additional optical couple.

20. The thickness monitor according to claim 19 wherein the optical couple is an optical fiber.

21. The thickness monitor according to claim 20 wherein the optical fiber is a plurality of optical fibers.

22. The thickness monitor according to claim 18 wherein the coupling system and the supplementary coupling system are selected to be capable of transmitting a broad spectral range of captured radiation from the at least one probe to the at least one detector.

23. The thickness monitor according to claim 7 wherein the at least one radiation source is polychromatic.

24. The thickness monitor according to claim 23 wherein the polychromatic radiation includes at least one of ultraviolet radiation, visible radiation, infrared radiation, and combinations thereof.

25. The thickness monitor according to claim 9 wherein the at least one source radiation is monochromatic.

26. The thickness monitor according to claim 9 further including an additional radiation source.

27. The thickness monitor according to claim 23 wherein the additional radiation is polychromatic.

28. The thickness monitor according to claim 27 wherein the additional polychromatic radiation is at least one of ultraviolet radiation, visible radiation, infrared radiation, and combinations thereof.

29. The thickness monitor according to claim 26 wherein the additional radiation is monochromatic.

30. The thickness monitor according to claim 26 wherein a spectral range of the at least one radiation source and a spectral range of the additional radiation source partially overlap.

31. The thickness monitor according to claim 30 wherein the partial overlap increases at least one of a signal to noise ratio for the captured radiation, a total spectral range of captures radiation, and combinations thereof.

32. The thickness monitor according to claim 26 wherein one of the at least one radiation source and the additional radiation source is visible radiation and the other of the at least radiation source and the additional radiation source is infrared radiation.

33. The thickness monitor according to claim 9 wherein the at least one probe further includes a collimator.

34. The thickness monitor according to claim 33 wherein the collimator facilities a depth of field of a sufficient value to measure the product thickness.

35. The thickness monitor according to claim 9 wherein the at least one probe substantially juxtaposes the coating applicator.

36. The thickness monitor according to claim 9 wherein the at least one probe is substantially separate of the coating applicator.

37. The thickness monitor according to claim 9 wherein the at least one detector includes an interferometer.

38. The thickness monitor according to claim 9 wherein the processing of the captured radiation to determine the thickness by the thickness monitor includes at least one of:
(a) using a color;
(b) using an interference pattern;
(c) using an amount of absorbed radiation;
(d) using an intensities ratio of a minimum reflected radiation wavelength and a maximum reflected radiation wavelength;
(e) using a Fast Fourier Transformation (FFT) of the captured radiation;
(f) displacement using eddy current;
(g) displacement using capacitance;
(h) displacement using an optics or laser; and
(i) combinations thereof.

39. The thickness monitor according to claim 9 wherein the processing of the captured radiation to determine the thickness by the thickness monitor includes using a Fast Fourier Transformation (FFT) of the captured radiation.

40. An intelligent coating system for forming a product on at least a portion of a substrate, the intelligent coating system including:
(a) a coating applicator;
(b) a thickness monitor for measuring the thickness of at least a portion of the product on the substrate formed by operation of the coating applicator, the thickness monitor including:
(i) at least one radiation source capable of being directed at at least a portion of the product on the substrate,
(ii) at least one probe capable of capturing at least a portion of the radiation reflected and refracted by the product on the substrate, the captured radiation being at least a portion of the radiation directed at the product on the substrate from the radiation source, and
(iii) at least one detector in communication with the at least one probe, the at least one detector capable of processing the captured radiation to determine at least the thickness of the product on the coated substrate, where the thickness monitor is capable of converting the coating system into an intelligent coating system;
(c) a multiple-axis device capable of facilitating a relative movement of at least a portion of the coating applicator and the substrate; and
(d) at least one controller in communication with at least the thickness monitor.

41. A method for teaching a coating system to form a product on at least a portion of a substrate by coating the substrate, said method including:
(a) setting the operating parameters of the coating process to initial prescribed operating parameters;
(b) applying a coating to at least a portion of the substrate thereby creating the product while at the same time recording the operating parameters of the coating process;
(c) measuring a thickness of at least a portion of the product on the substrate, the measuring including:
(i) communicating with at least a portion of the product on the substrate without contacting either, and
(ii) processing the communication with the at least a portion of the product to allow a determination of at least the thickness of the product on the substrate;
(d) relating the operating parameters and the product thickness with the location the substrate;
(e) determining whether a product thickness distribution meets a prescribed product thickness distribution;
(f) if the product thickness distribution meets the prescribed product thickness distribution, either:
(i) repeating steps (a) through (e) to build up the product thickness or
(ii) replacing the substrate with another substrate and repeating steps (a) through (e); otherwise:
(g) (i) replacing the substrate with another substrate,
(ii) setting the operating parameters of the coating process to secondary prescribed operating parameters, and
(iii) performing repeating steps (b) through (f); and
(h) reconciling the operating parameters and the product thickness of a plurality of coating runs to create a dynamic control of the coating system.
